(19) United States
(12) Patent Application Publication
(10) Pub. No.: US 2016/0293781 A1
(43) Pub. Date: Oct. 6, 2016

(54) THREE DIMENSIONAL ANTI-REFLECTION NANOCONE FILM

(71) Applicant: THE HONG KONG UNIVERSITY OF SCIENCE AND TECHNOLOGY, Kowloon, Hong Kong (CN)

(72) Inventors: Zhiyong FAN, Kowloon, Hong Kong (CN); Kwong Hoi TSUI, New Territories, Hong Kong (CN); Qingfeng LIN, Kowloon, Hong Kong (CN)

(21) Appl. No.: 15/038,450

(22) PCT Filed: Nov. 21, 2014
(86) PCT No.: PCT/CN2014/091880

§ 371 Date: May 20, 2016

Related U.S. Application Data
(60) Provisional application No. 61/963,020, filed on Nov. 21, 2013.

(51) Int. Cl. H01L 31/0216; H01L 31/073; H01L 31/18

(52) U.S. Cl. CPC H01L 31/02168; H01L 31/18; H01L 31/073

(57) ABSTRACT

Disclosed are three-dimensional nanocone film layers and associated devices. The nanocone film layers exhibit desirable properties such as anti-reflection, hydrophobicity, and low cost production. The nanocone film layers can be utilized to cover the surface of a photovoltaic cell and provide benefits to the photovoltaic cell such as enhance its light absorption capability, provide protection from moisture, increase efficiency of converting light to electricity, facilitate self-cleaning, and other such benefits. Furthermore, in an aspect, methods of fabricating three-dimensional nanocone film layers are disclosed herein.

### RELATED APPLICATION

This application claims priority to U.S. Provisional Patent Application No. 61/963,020, entitled “LOW-COST AND FLEXIBLE THREE-DIMENSIONAL NANOCONE ANTI-REFLECTION FILMS WITH SELF-CLEANING FUNCTION FOR HIGH-EFFICIENCY PHOTOVOLTAICS,” and filed on Nov. 21, 2013, the entirety of which is incorporated herein by reference.

### TECHNICAL FIELD

The subject disclosure relates generally to nanocone films, fabrication of nanocone films and to applications where nanocone films can be utilized for its anti-reflective properties, hydrophobic properties, ability to promote removal of debris, and other such uses.

### BACKGROUND

There is an increasing demand for enhancing the efficiency of photovoltaic devices. A photovoltaic device operates by capturing solar energy and converting the solar energy to electrical energy. One very important capability of the photovoltaic cell is to capture incident light for conversion to electrical energy thereby resulting in a more efficient photovoltaic cell. One method of strengthening the capability to capture incident light is to reduce reflection of light away from the photovoltaic cell. An anti-reflective coating can be applied to the surface of a photovoltaic cell to increase the capture of incident light and reduce the reflection of light. In recent years, one of the greatest challenges is to reduce the cost and improve the performance of photovoltaic devices using anti-reflective coatings.

Traditionally, quarter-wavelength (λ/4) anti-reflective coatings and other such anti-reflective coatings have been widely employed to reduce light reflection on the surface of photovoltaic devices. However, current anti-reflective coatings possess limited effectiveness in capturing incident light because the anti-reflective efficacy of the coatings are dependent on the wavelength of the incoming light wave, the angle of incidence light contacts the photovoltaic cell surface, and whether incident light faces interference upon contact with the photovoltaic cell. Interference can occur when debris, oil or other material collect at the surface of the photovoltaic cell. Another limitation of current anti-reflective coatings is that they require expensive chemical and physical deposition processes for fabrication, which often result in large-scale production being cost prohibitive. Furthermore, many of the fabrication processes incorporate photovoltaic materials into microstructures which can lead to defects that increase surface recombination of the coating material and ultimately lower the performance of the solar device. Moreover, current coating fabrication methods can implement top-down or bottom-up fabrication methods that inhibit control and precision related to the desired end product.

There is a need for new photovoltaic cell coatings and fabrication methods to address the issues of poor anti-reflection capabilities, expensive fabrication, diminished energy conversion, limited light absorption, and accumulation of surface debris as relates to photovoltaic cell coatings.

### SUMMARY

The following presents a simplified summary in order to provide a basic understanding of some aspects disclosed herein. This summary is not an extensive overview. It is intended to neither identify key or critical elements nor delineate the scope of the aspects disclosed. Its sole purpose is to present some concepts in a simplified form as a prelude to the more detailed description that is presented later.

Devices and methods of fabricating such devices are provided to inhibit reflection of light, facilitate capture of more light by photovoltaic cells, enhance the efficiency of converting light to electricity, provide moisture protection, and promote self-removal of debris. In one aspect, a device is provided that includes a nanocone layer comprising a first material; and a substrate layer comprising a second material, wherein the nanocone layer and the substrate layer form a flexible nanocone film that comprises an anti-reflective property, wherein the flexible nanocone film coats a photovoltaic device intended to absorb light and convert energy, and wherein the nanocone film facilitates increased light absorption by the photovoltaic device relative to the nanocone film coating being absent and increased energy conversion output of the photovoltaic device relative to the nanocone film coating being absent.

In another aspect, a method is provided that includes imprinting a nanoindentation array on a surface of an electrochemically polished aluminum foil layer with a stamp element comprising silicon nanopillars ordered in a hexagonal pattern resulting in an imprinted surface; performing electrochemical anodization and wet chemical etching on the imprinted surface of the electrochemically ordered aluminum foil layer to fabricate an aluminum i-cone array; applying a premixed solution comprising polydimethylsiloxane onto the aluminum i-cone array resulting in a polydimethylsiloxane nanocone film; and removing a polydimethylsiloxane nanocone film from the aluminum i-cone array. In an aspect, the method can further comprise sputtering a gold film on the imprinted surface, wherein the gold film inhibits sticking of polydimethylsiloxane to the aluminum i-cone array when removing the polydimethylsiloxane nanocone film.

In yet another aspect, a device is provided comprising a cadmium telluride material; and a polydimethylsiloxane nanocone film covering a surface of the photovoltaic cell, wherein the polydimethylsiloxane nanocone film comprises a nanocone array pattern layer and a substrate layer, and wherein the photovoltaic cell has enhanced anti-reflective properties as compared to the photovoltaic cell absent the polydimethylsiloxane nanocone film covering, increased energy conversion capabilities as compared to the photovoltaic cell absent the polydimethylsiloxane nanocone film covering, and increased energy output as compared to the photovoltaic cell absent the polydimethylsiloxane nanocone film covering.

To the accomplishment of the foregoing and related ends, the subject disclosure then, comprises the features hereinafter fully described. The following description and the annexed drawings set forth in detail certain illustrative aspects. However, these aspects are indicative of but a few of the various ways in which the principles disclosed herein may be employed. Other aspects, advantages and novel features will become apparent from the following detailed description when considered in conjunction with the drawings.

### BRIEF DESCRIPTION OF DRAWINGS

FIG. 1 illustrates a non-limiting schematic block diagram of a flexible nanocone film with anti-reflective properties coating a photovoltaic cell.

FIG. 2 illustrates a non-limiting schematic block diagram of a polydimethylsiloxane nanocone film coating a cadmium telluride photovoltaic cell.

with anti-reflective properties

FIGS. 3(A-D) illustrate a non-limiting method of fabricating a flexible nanocone film.

FIG. 3(E) is an image of a gold film on the surface an aluminum foil layer.

FIG. 3(F) is an image of nanocone rows of a flexible nanocone film with each nanocone having a 1 μm pitch and 1 μm depth.

FIG. 4(A) is an image of a flexible nanocone film.

FIG. 4(B) illustrates a schematic structure of a photovoltaic cell surface covered by a polydimethylsiloxane nanocone film.

FIG. 4(C) is an image of a polydimethylsiloxane nanocone film covering the surface of a cadmium telluride device.

FIG. 4(D) is an image of a drop of water contacting the surface of a polydimethylsiloxane nanocone film at a large contact angle of 152°.

FIG. 4(E) is an image of a drop of water contacting the surface of a planar polydimethylsiloxane film at a contact angle of 98°.

FIG. 5(A) illustrates a diagram comparing the reflectance spectra of a photovoltaic cell covered with a polydimethylsiloxane nanocone film as compared to a photovoltaic cell in the absence of a polydimethylsiloxane nanocone film covering.

FIG. 5(B) is a graph illustrating J-V curves of a photovoltaic cell covered with a polydimethylsiloxane nanocone as compared to a photovoltaic cell in the absence of a polydimethylsiloxane nanocone film covering.

FIG. 5(C) is a graph illustrating the Quantum Efficiency measurement of a photovoltaic cell covered with a polydimethylsiloxane nanocone film as compared to a photovoltaic cell in the absence of a polydimethylsiloxane nanocone film covering.

FIG. 5(D) is a graph illustrating the power output improvement of a photovoltaic cell covered with a polydimethylsiloxane nanocone film as compared to a photovoltaic cell in the absence of a polydimethylsiloxane nanocone film covering.

FIG. 6 illustrates a non-limiting example method of fabricating an anti-reflective device.

FIG. 7 illustrates a non-limiting example method of fabricating an anti-reflective device.

FIG. 8 illustrates a non-limiting example method of fabricating an anti-reflective device.

### DETAILED DESCRIPTION

Flexible nanocone film devices are provided to increase the capability of a photovoltaic cell to absorb light. Methods of fabricating flexible nanocone films are also provided. Recently, photovoltaic cells (also referred to as solar cells) have gained popularity as a form of alternative energy around the world. Photovoltaic cells are utilized as a means of converting sunlight directly into electricity and are often a cheaper source of energy for consumers and a viable alternative to burning fossil fuels for electricity. Given the growing popularity of photovoltaic cells there is a need to increase the efficacy of its capability to convert sunlight into electricity, reduce the cost associated with fabricating more efficacious devices, and improve its overall performance.

Disclosed herein are three-dimensional flexible nanofilms that incorporate nanostructures, which possess anti-reflective properties, facilitate increased light absorption and promote efficient charge separation as a result of its large surface area and three-dimensional structure. The flexible nanofilms can be coated on a photovoltaic material to facilitate more efficient light absorption and conversion of light into electricity. Furthermore, the flexible nanofilms comprise hydrophobic properties that promote cleaning of the nanofilms by merely having water runoff the surface of the nanofilm. In an aspect, disclosed are films comprising a three-dimensional nanopillar array on aluminum foil wherein the height and pitch of the three dimensional nanopillar structure dimensions can be customized.

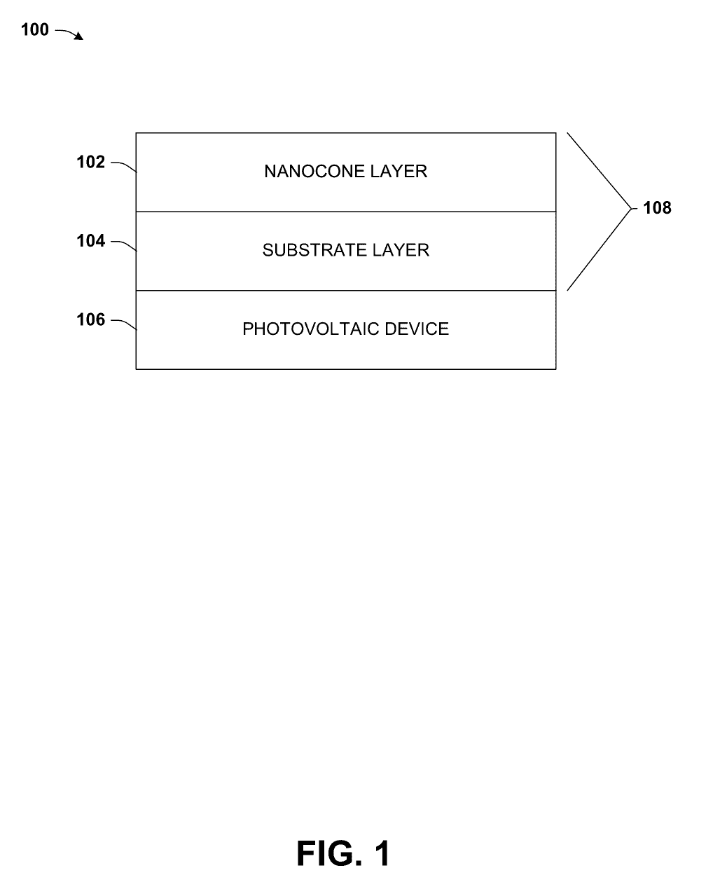

Referring initially to FIG. 1, an antireflection device 100 is illustrated. The device 100 includes a nanocone layer 102 comprising a first material and a substrate layer 104 comprising a second material, wherein the nanocone layer 102 and the substrate layer 104 form a flexible nanocone film 108 that comprises an anti-reflective property. In an aspect, the flexible nanocone film 108 coats a photovoltaic device 106 intended to absorb light and convert energy, and wherein the nanocone film 108 facilitates increased light absorption by the photovoltaic device 106 relative to the nanocone film 108 coating being absent and increased energy conversion output of the photovoltaic device 106 relative to the nanocone film 108 coating being absent.

In an aspect, the first material of nanocone layer 102 can be polydimethylsiloxane (PDMS) with anodic alumina and the second material of the substrate layer 104 can be an aluminum (Al) substrate. Regarding the first material of nanocone layer 102, PDMS has many attractive qualities such as being inexpensive, environmentally friendly, resistant to harsh weather conditions, and mechanically elastic. Furthermore, PDMS is transparent and such optical clarity allows light to pass through the material, which is a suitable quality for purposes of facilitating light absorption to a photovoltaic cell. In another aspect, the first material of nanocone layer 102 can be other plastic material with qualities (e.g. material flexibility and durability) similar to PDMS such as polycarbonate or polyimide. In another aspect, the first material can also comprise an anodic alumina material molded to the PDMS.

The nanocone layer 102 and substrate layer 104 together form a flexible nanocone layer 108. The nanocone layer 102 can comprise the first material formed into hexagonally ordered nanocones also referred to as nanopillars via a fabrication process that makes use of a nanopillar i-cone array. The nanopillar i-cone array is a template mold that allows PDMS to take the shape of nanocone structures. Structurally, nanopillars offer favorable dimensions for the nanocone layer 102 in that they possess large surface areas and three-dimensional features that provide a larger area exposed to light. Furthermore, in an aspect, the nanopillars provide a larger anti-reflective area to promote absorption of light contacting the surface of the nanopillars at many angles.

In another aspect, the nanopillars as a part of the nanocone layer 108 are employed in connection with a photovoltaic device 106 in providing enhanced photon absorption and efficient charge separation between an excited electron (e.g., electron excitation via an absorbed photon) and the corresponding hole. As a photovoltaic device 106 becomes more efficient at charge separation between a negatively charged electron and a positively charged hole (also referred to as an exciton), more current can be generated by the photovoltaic device 106 and less energy is required to generate such current. The efficiency of the photovoltaic device 106 in generating energy can also be affected by controlling the height and pitch of one or more of the nanopillars of the nanocone layer 102.

In an aspect, the nanocone film 108 can be used as a coating on the surface of a photovoltaic device 106. A photovoltaic device 106 is a device that generates electric power by converting sunlight into electricity. In an aspect, a photovoltaic device 106 can be comprised of multiple solar cells grouped contiguously and oriented in one direction, also referred to as a solar panel or photovoltaic panel. The photovoltaic device 106 utilizes materials that exhibit a photovoltaic effect, which is the creation of voltage or current in a material upon exposure to light. In an aspect the nanocone film 108 can significantly improve performance of a photovoltaic device 106 (as compared to a photovoltaic device 106 absent a nanocone film layer coating 108) owing to the antireflective properties of the coating. The antireflective properties in turn result in more efficient light absorption by the photovoltaic device 106 as evidenced by higher short current density (J_{SC}) production by the photovoltaic device 106.

In an aspect, the photovoltaic device 106 can comprise a sheet of glass covering the material that exhibits a photovoltaic effect, such as a semiconductor wafer. The glass covering can protect the material that exhibits the photovoltaic effect while also providing a transparent surface through which light can pass for absorption by the material. In an aspect, the PDMS first material of the nanocone film 108 can be attached to a flat glass substrate (e.g. as a result of strong Van der Waals interaction between PDMS and glass) thereby allowing the nanocone film 108 to be mounted on a solar cell surface of a photovoltaic device 106. The self-attachable property of PDMS allows for convenient mounting (e.g. without the need for adhesives) and facilitates user-friendly replacement of the nanocone film 108.

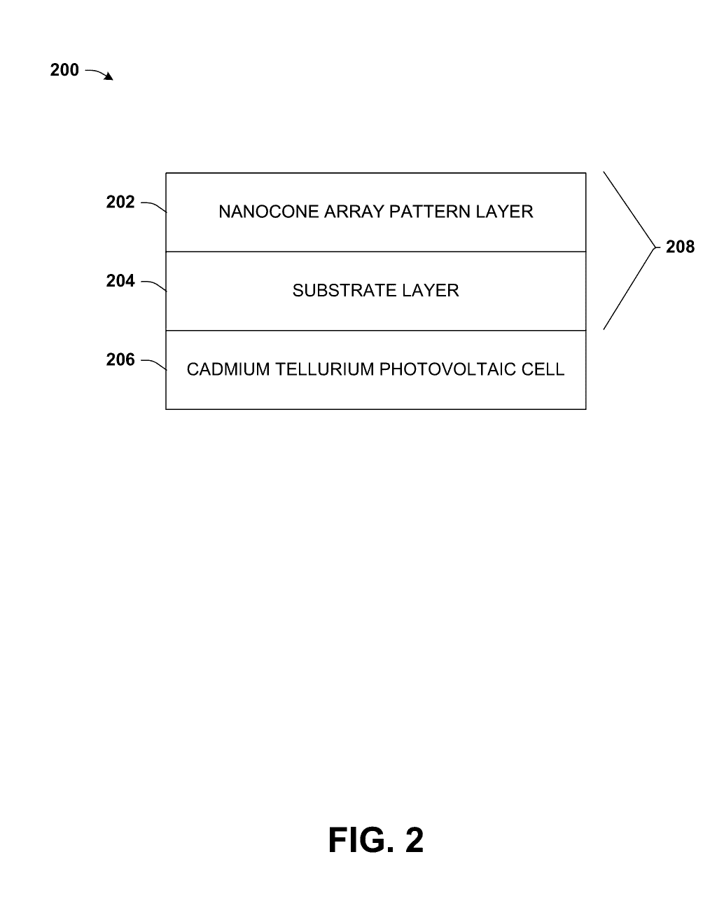

Referring briefly to FIG. 2, illustrated is a non-limiting example device 200. The device 200 includes a photovoltaic cell 206 comprising a cadmium telluride (CdTe) material, a PDMS nanocone film 208 covering a surface of the photovoltaic cell, wherein the PDMS nanocone film 208 comprises a nanocone array pattern layer 202 and a substrate layer 204, and wherein the photovoltaic cell 206 has enhanced anti-reflective properties as compared to the photovoltaic cell absent the PDMS nanocone film 208 covering, increased energy conversion capabilities as compared to the photovoltaic cell absent the PDMS nanocone film 208 covering, and increased energy output as compared to the photovoltaic cell 206 absent the PDMS nanocone film 208 covering.

Similar to device 100 in FIG. 1, device 200 comprises a nanocone film 208 comprising PDMS and a substrate such as aluminum. In an aspect, the nanocone film 208 takes the form of a pattern such as rows of protruding three-dimensional nanocones, which comprise the nanocone array pattern layer 202. In a non-limiting example embodiment, the nanocone array pattern layer 202 can comprise at least two nanocones according to a pattern comprising a pitch of at least 1 μm and a height of at least 1 μm. The pitch and height of each nanocone can be fabricated to different sizes to garner different hydrophobic and light absorption properties. In a non-limiting embodiment, the nanocone array pattern layer 202 can comprise structures and morphologies other than nanocones such as nanospheres, nanotubes, nanorods, nanowires, or porous films.

In another aspect, device 200 comprises a cadmium telluride photovoltaic cell 206. A cadmium telluride photovoltaic cell 206 comprises a thin semiconductor layer cadmium telluride material capable of absorbing and converting sunlight into electricity. In an aspect, photovoltaic cell 206 can be comprised of a silicon layer, however, cadmium telluride is significantly cheaper than silicon, which can lead to cost efficient manufacturing and lower per watt electricity prices to consumers. The cheaper cost is in part due to the abundance of cadmium material and the ease of making the material (e.g. mixing molecules) as compared to the multi-step process required to join different types of silicon and doped silicon in relation to a silicon based photovoltaic cell. In another aspect, other non-limiting embodiments of device 200 can be implemented, such as varying the material composition of the photovoltaic cell 206 to comprise a copper indium gallium selenide photovoltaic cell or a silicon photovoltaic cell.

A limitation of a cadmium telluride photovoltaic cell 206 in the absence of nanocone film 208 is the lower efficiency than silicon photovoltaic cells to convert sunlight into electricity. In an aspect, to address such limitation, the attachment of a nanocone film 208 to the cadmium telluride photovoltaic cell 206 provides an anti-reflective covering that enhances the capability of photovoltaic cell 206 to absorb light and convert light energy into electricity. Not only does device 200, allow more light into the photovoltaic cell 206 by minimizing sunlight reflection, but the additional absorbed sunlight is collected more efficiently to facilitate greater electrical current generation. Additionally, device 200 is cost effective to manufacture versus a silicon photovoltaic cell, while maintaining higher levels of efficient energy conversion.

Another benefit associated with device 200 is the ability to minimize exposure to moisture. In an aspect, device 200 has increased hydrophobic properties as compared to the device absent the PDMS nanocone film 208 covering wherein the increased hydrophobic properties facilitate removal of debris from the device by promoting water to drip off the surface of the PDMS nanocone film 208. The drip-off water effectively cleans the surface of device 200 in that it carries away debris and other material from the device 200 surface that would otherwise obstruct or inhibit the absorption of light.

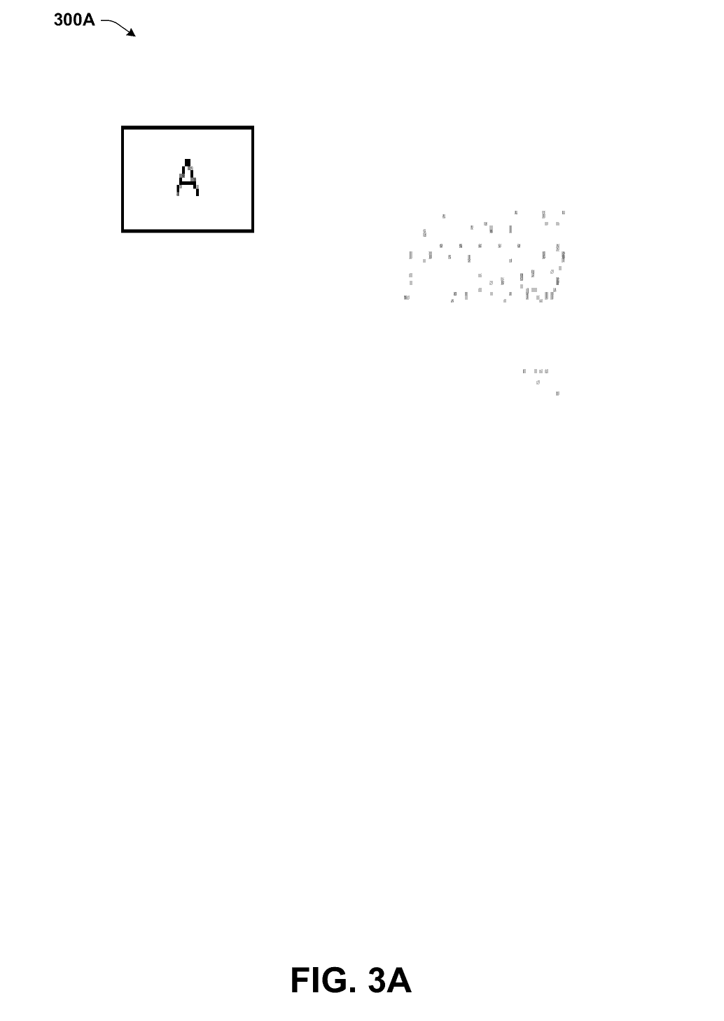

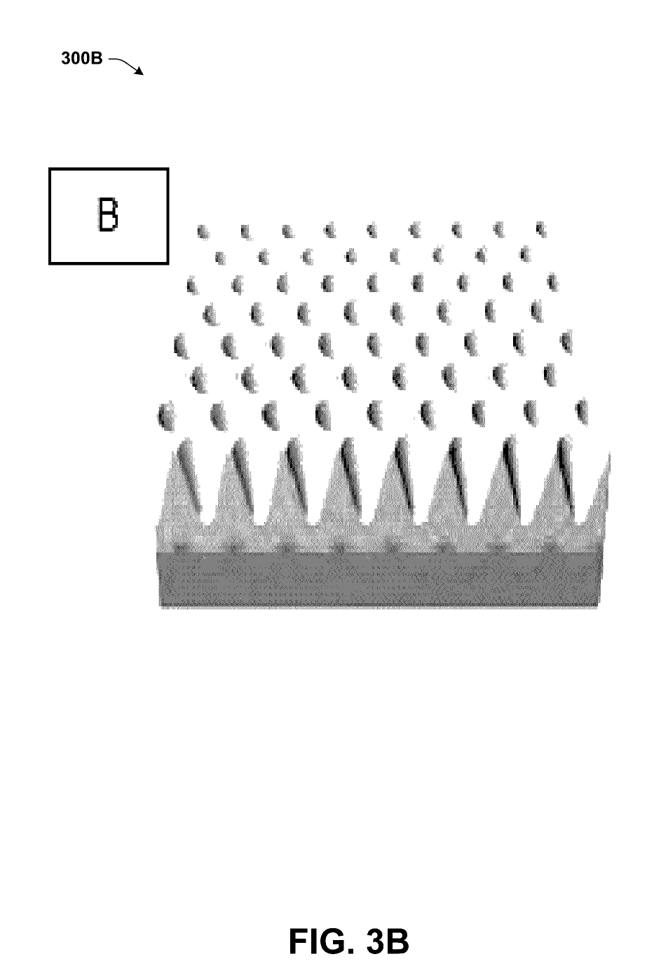

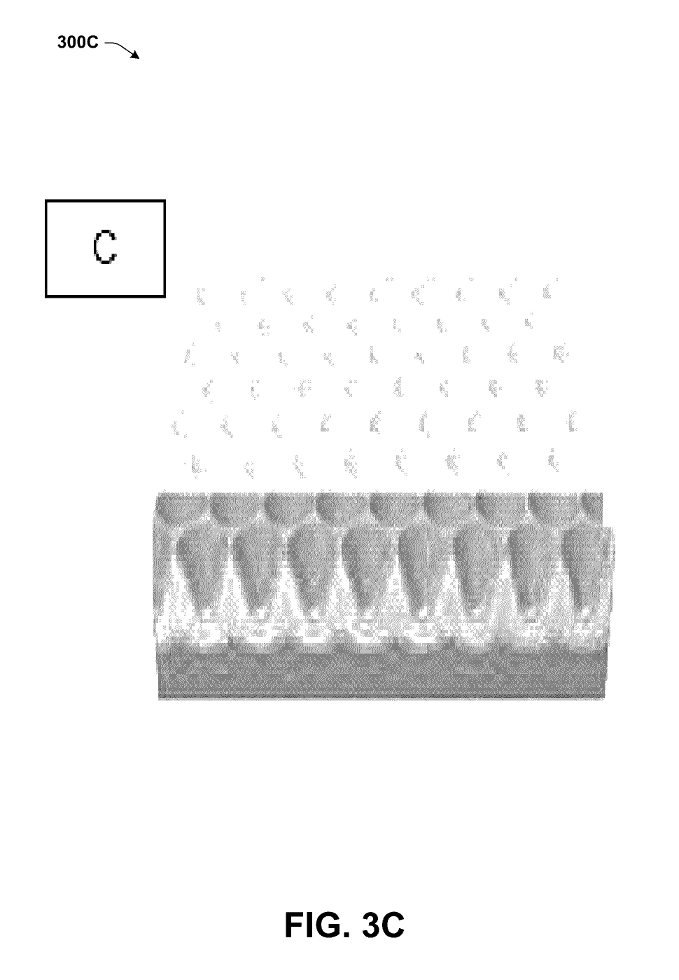

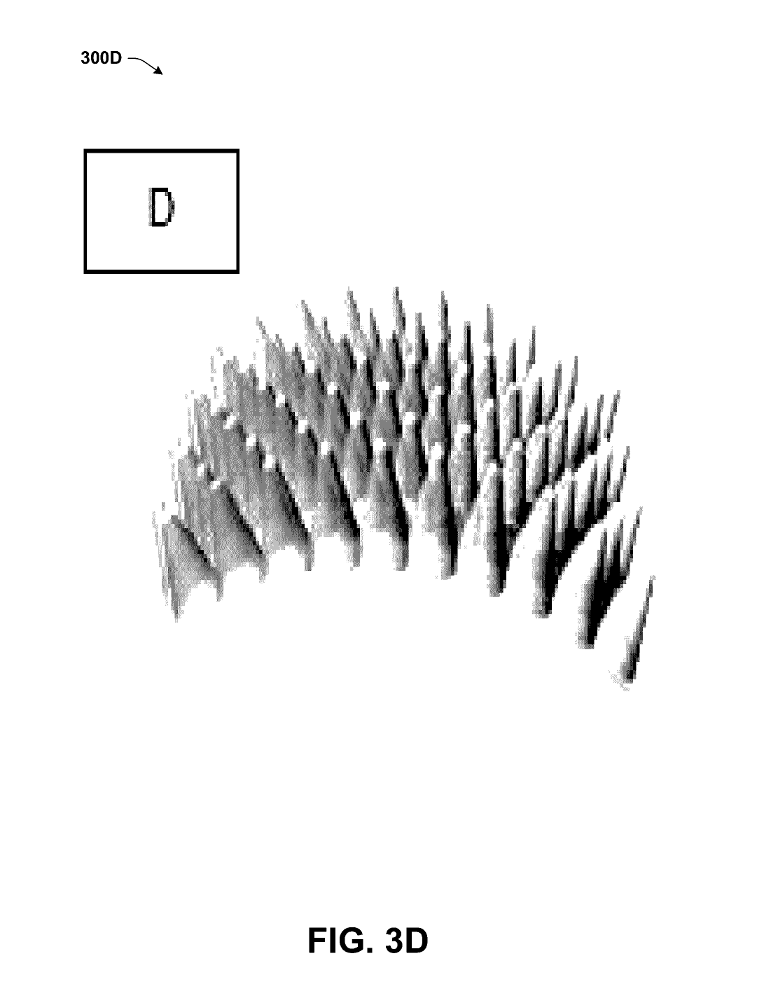

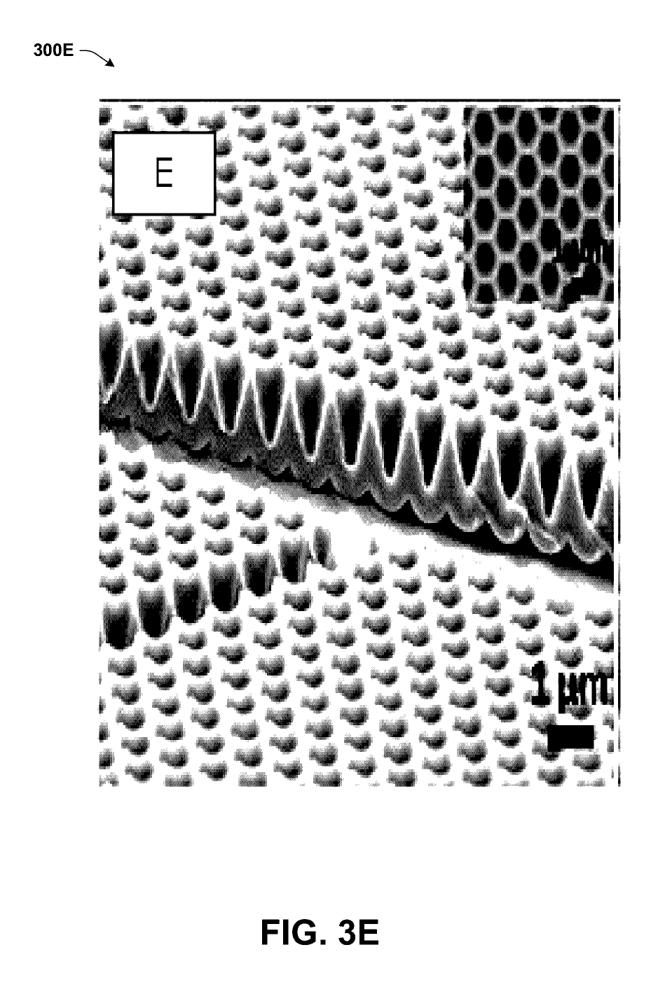

Turning now to FIGS. 3(A-F), illustrated are images 300A-300F of a nanocone layer 102 and methods of fabricating the nanocone layer 102. In an aspect, FIG. 3(A) illustrates a silicon (Si) mold with hexagonally ordered nanopillars wherein the mold is utilized to imprint an array of nanopillar indentations. In an aspect, the silicon mold comprising hexagonally ordered nanopillars can be used to stamp an electrochemically polished aluminum (Al) foil resulting in an array of nanopillar indentations on the aluminum foil surface. In a non-limiting example embodiment, the nanopillars can possess a height of 200 nm and a tunable pitch of between 500 nm to ˜2 μm. FIG. 3(B) illustrates an i-cone array fabricated by a multi-step anodization and wet etching process on the imprinted aluminum foil while the aluminum foil is within an acidic solution and a direct current (DC) voltage is applied to such solution.

Also, in an aspect, the aluminum i-cone array can be coated with a gold (Au) film measuring a 50 nm measurement. In an aspect the gold film can be sputtered on the surface of the aluminum i-cone array to prevent sticking or residual remnants of subsequently added PDMS and also facilitate removal of the subsequently added PDMS layer. Turning to FIG. 3(C), illustrated is an image of the gold-coated i-cone array wherein a premixed PDMS is poured over the gold-coated i-cone array. In an aspect, a degassing and curing process can be applied to the gold-coated i-cone array layered with PDMS. At FIG. 3(D), illustrated is an image of a nanocone film layer 108 peeled off of the gold-coated i-cone array. At FIG. 3(E), illustrated is a Scanning Electron Microscope (SEM) image of a gold-coated i-cone array template comprising nanocone indentations with a 1 μm pitch and 1 μm depth. At FIG. 3(F), illustrated is a SEM image of a nanocone film 108 comprised of rows of nanocones wherein each nanocone has a 1 μm pitch and 1 μm depth.

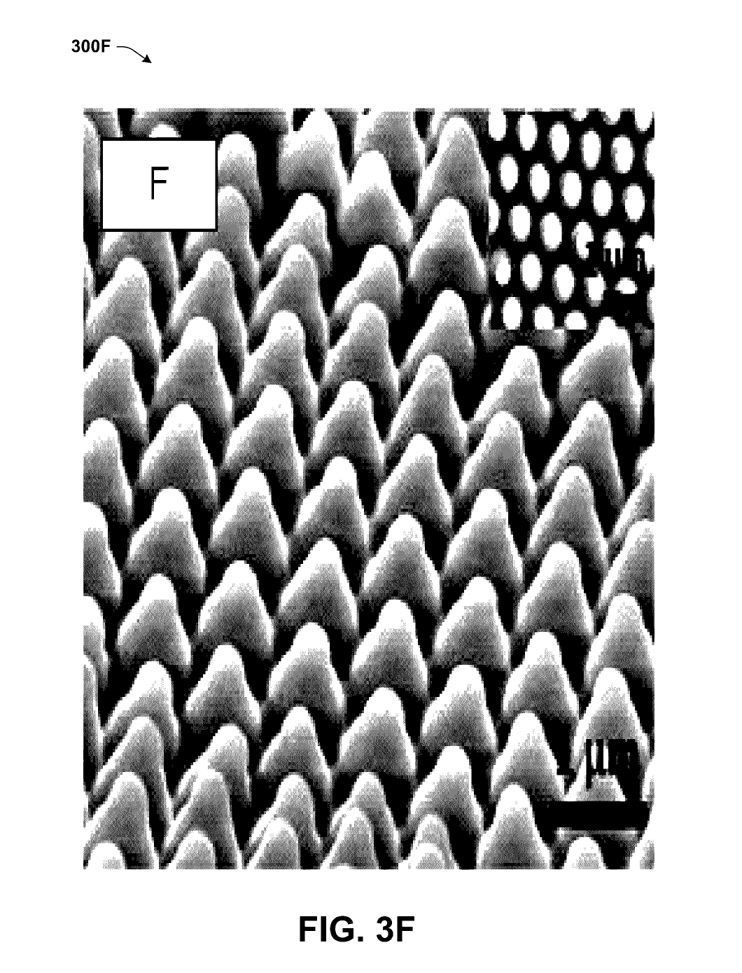

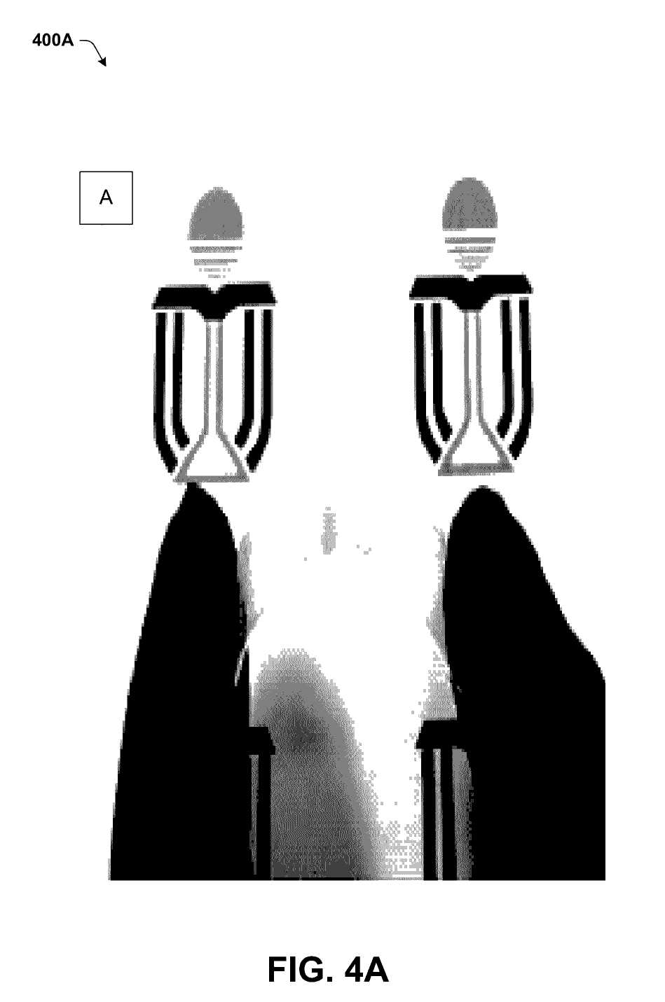

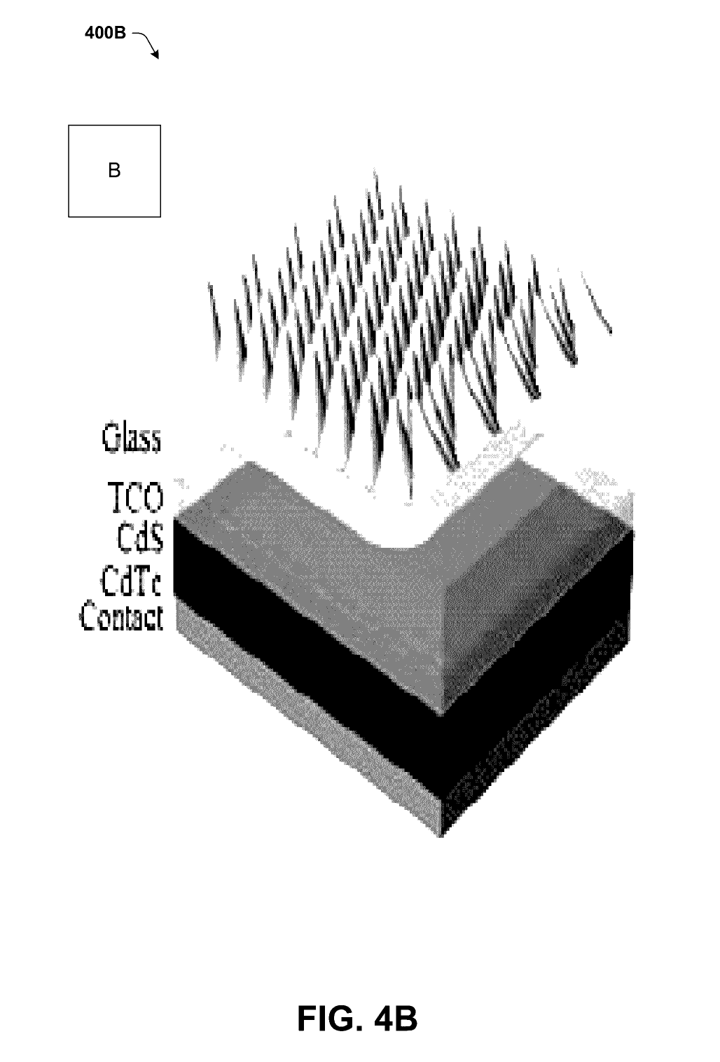

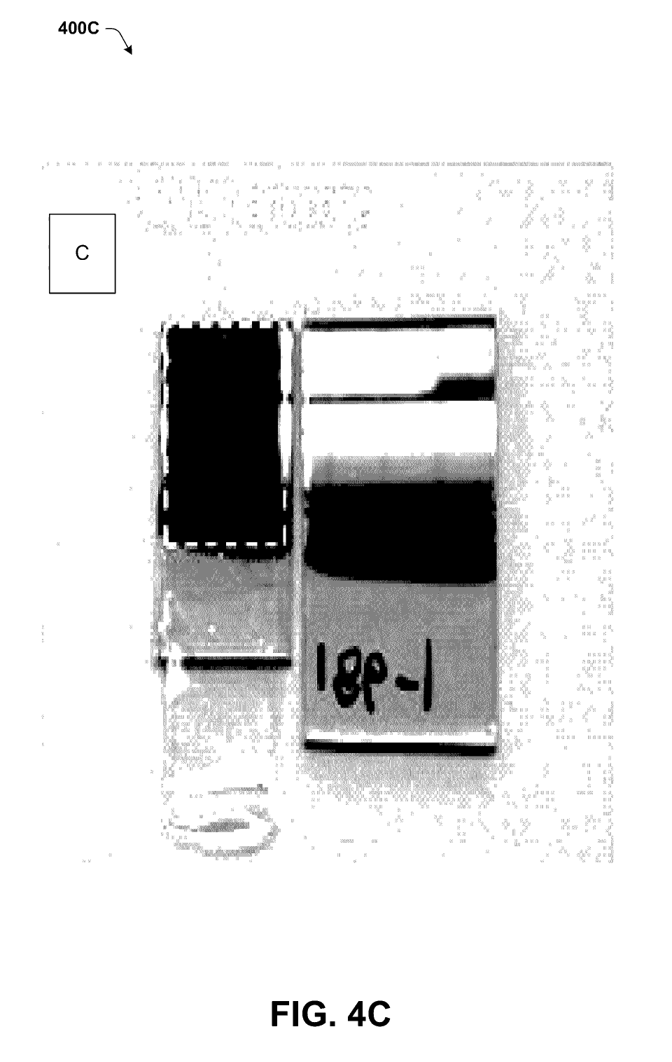

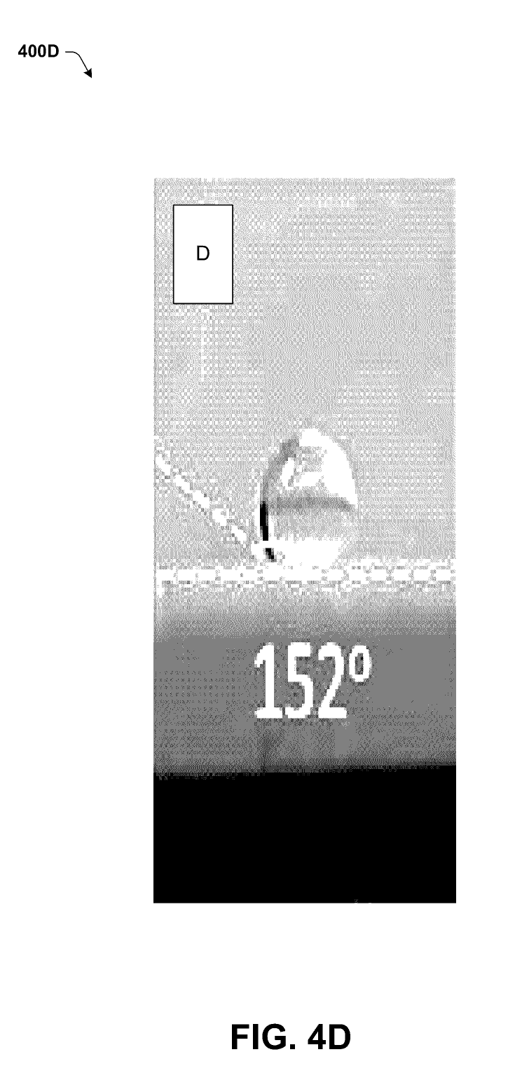

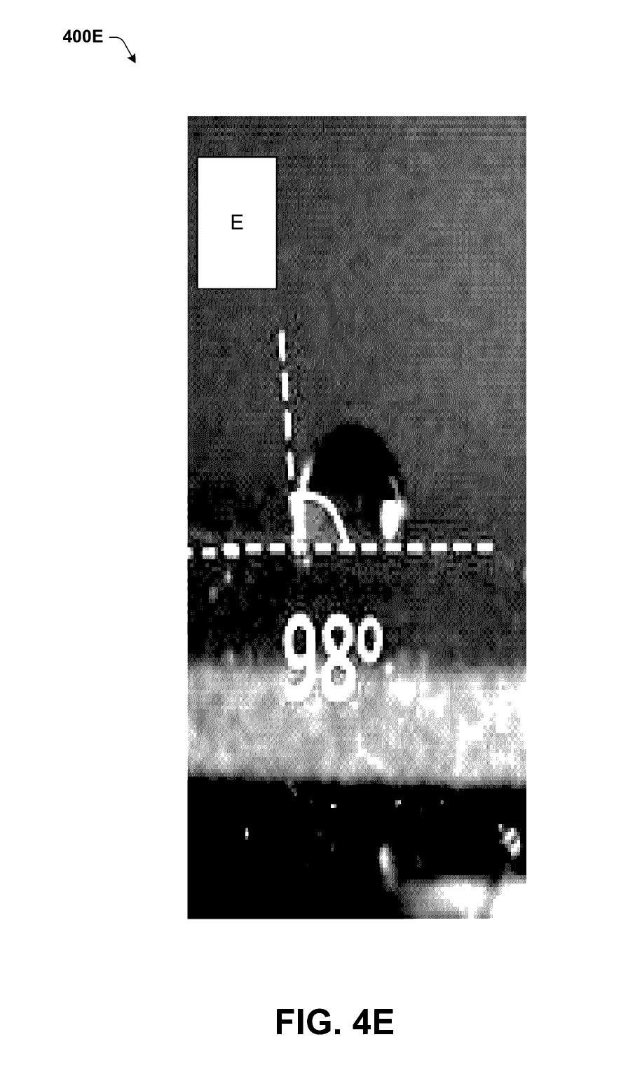

Referring now to FIGS. 4(A-E), FIG. 4(A) is an image of a flexible nanocone film layer 108. At FIG. 4(B) is a non-limiting example illustration of a photovoltaic cell 106 covered with a nanocone film layer 108. In an aspect, disclosed is a photovoltaic cell 106 with many layers such as a cadmium telluride layer, a cadmium sulfide layer, a transparent conductive oxide layer (TCO), a glass layer and a nanocone film layer 108. The nanocone film 108 can be a covering for a wide range of photovoltaic cells comprising many material compositions. At FIG. 4(C), presented is an image of a nanocone film 108 at the surface of a cadmium telluride photovoltaic device 106 and the antireflective visual effect of such device. The object to the left is a cadmium telluride photovoltaic device 106 covered by a nanocone film 108 and the object to the right by comparison is a cadmium telluride photovoltaic device 106 absent a nanocone film 108 covering. The object to the left conspicuously shows the suppression of the reflectance of light whereas the object on the right demonstrates the clear reflection of the in-door fluorescence lamp.

At FIG. 4(D), presented is an image of a drop of water suspended at the surface of the PDMS nanocone film 108 wherein the angle of contact of the water droplet to the surface of the nanocone film layer is 152°. At FIG. 4(E), presented is another drop of water suspended at the surface of a flat PDMS film (as opposed to a three-dimensional nanocone PDMS film) at a contact angle of 98°. As compared to a flat PDMS film, the nanocone film layer comprising PDMS material demonstrates an improvement in hydrophobicity partly due to the three dimensional nanocone structure. FIGS. 4(D) and 4(E) demonstrate the hydrophobic nature of the nanocone film 108 as evidenced by the suspension and structural integrity of each water droplet atop the surface of the nanocone film 108. Furthermore, in an aspect, given the hydrophobic nature of the nancone film 108, water can easily drip off the film layer surface simultaneously cleaning the film surface and protecting the layers underneath the film from moisture damage.

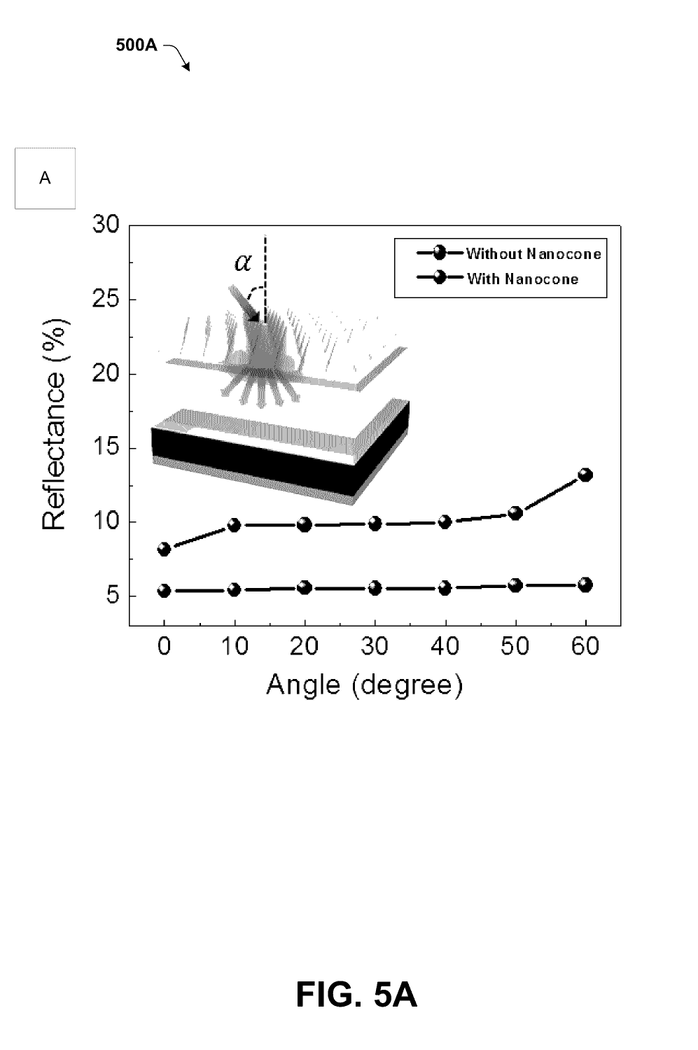

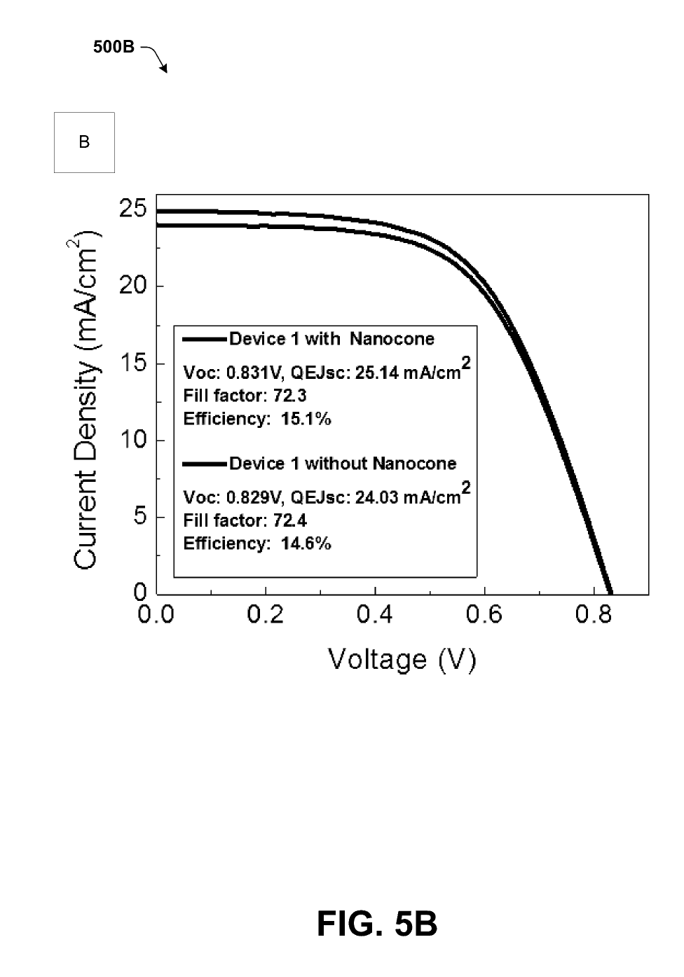

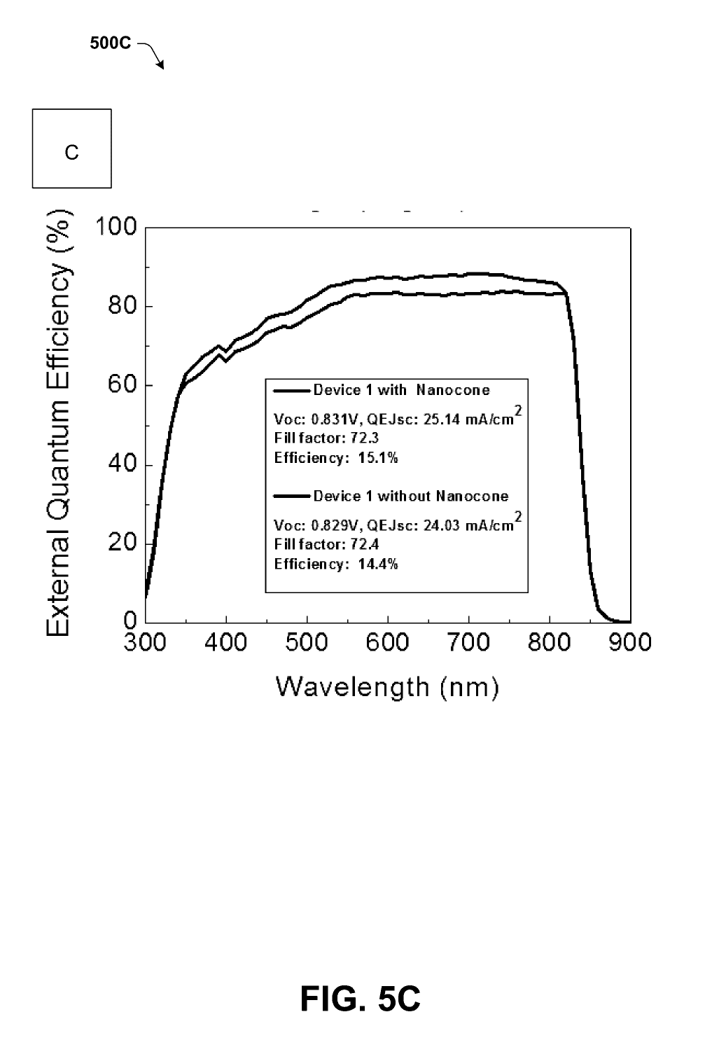

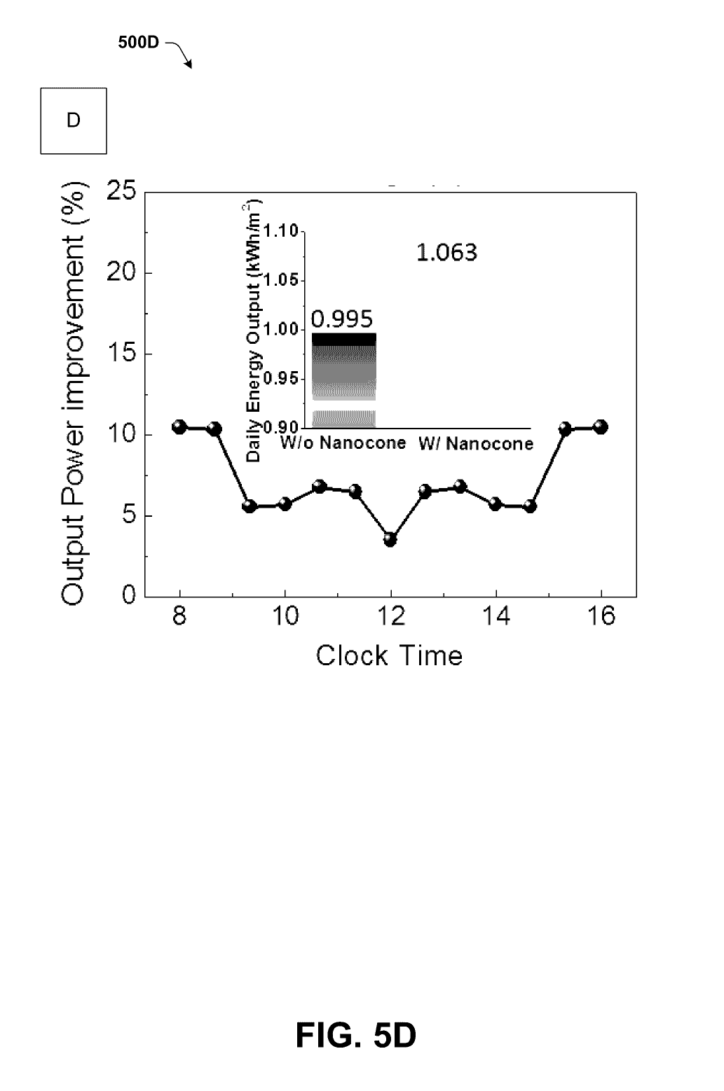

Referring now to FIGS. 5(A-D), illustrated are charts that plot data related to various properties associated with device 200. At FIG. 5(A), illustrated is a chart that plots reflectance data of a cadmium telluride (CdTe) photovoltaic device 206 covered with the flexible nanocone film 208 and a chart that plots reflectance data of a cadmium telluride (CdTe) photovoltaic device 206 absent a flexible nanocone film 208 covering. The data quantitatively characterizes the anti-reflective effect of three-dimensional flexible nanocone film 208 comprising nanocones wherein the height and pitch are 1 μm on CdTe photovoltaic cells 206. The x-axis plots the incident angles light contacts the photovoltaic cell 206 starting from 0° (normal incident) and ending at 60° with 10° intervals. The y-axis plots the percentage of light reflected given a particular incident angle the light contacts the photovoltaic cell 206.

In an aspect, a photovoltaic cell absent a flexible nanocone film coating reflects a higher percentage of light as the angle at which the light rays contact the surface of the photovoltaic cell increase. Conversely, in an aspect, a photovoltaic cell surface covered by a flexible nanocone film coating statically reflects a minimal percentage of light regardless of the angle the light contacts the photovoltaic cell surface. Thus a photovoltaic cell surface covered by a flexible nanocone film coating reflects less light and absorbs more light. Also, the data demonstrates that the anti-reflective properties of the nanocone film 208 are more pronounced as light contacts the photovoltaic cell 206 at higher angles of incidence. Particularly, in an aspect, the efficiency of the photovoltaic cell 206 to convert light to electricity is improved by ˜10% when light contacts the nanocone film coating at a 60° incident angle

At FIG. 5(B), illustrated is a chart that references the power conversion efficiencies of a CdTe photovoltaic device 206 covered with the flexible nanocone film 208 as compared to the power conversion of a CdTe photovoltaic cell 206 absent a flexible nanocone film 208 covering. The chart identifies data obtained regarding open circuit voltage (V_{OC}), fill factor (FF) and (QEJ_{SC}) circuit current density. Each observation contributes to a finding wherein the power conversion efficiency of a CdTe photovoltaic cell 206 surface covered with the flexible nanocone film is 15.1% and the power conversion efficiency of a CdTe photovoltaic cell 206 absent the flexible nanocone film is 14.4%. The results demonstrate a ˜4.9% improvement of conversion efficiency which is substantial for a high performance CdTe photovoltaic cell 206.

At FIG. 5(C), illustrated is a chart that references the short circuit current density (QEJ_{SC}) of a CdTe device with and without a flexible nanocone film 208 covering. The circuit current densities were obtained as 25.14 mA/cm² and 24.03 mA/cm² from the QE measurement, respectively, which indicates a ˜4.6% enhancement of circuit current density by employing the nanocone film 208 covering on the surface of a CdTe photovoltaic cell 206. At FIG. 5(D), illustrated is a chart that evaluates the power output of the nanocone film 208 layer surface covered photovoltaic cell 206 throughout the day assuming normal incidence corresponding to noon time and 60° corresponding to 4 hrs away from noon time. The photovoltaic cell 206 covered with a nanocone film 208 demonstrates an all-day improvement of electrical power output. The daily power output is 1.063 kWh/m², which a photovoltaic cell 206 utilizing the nanocone film 208 as compared to a 0.995 kWh m² energy output in the absence of the nanocone film 208, which translates to a 7% enhancement in power output by the photovoltaic cell that utilizes the nanocone film 208.

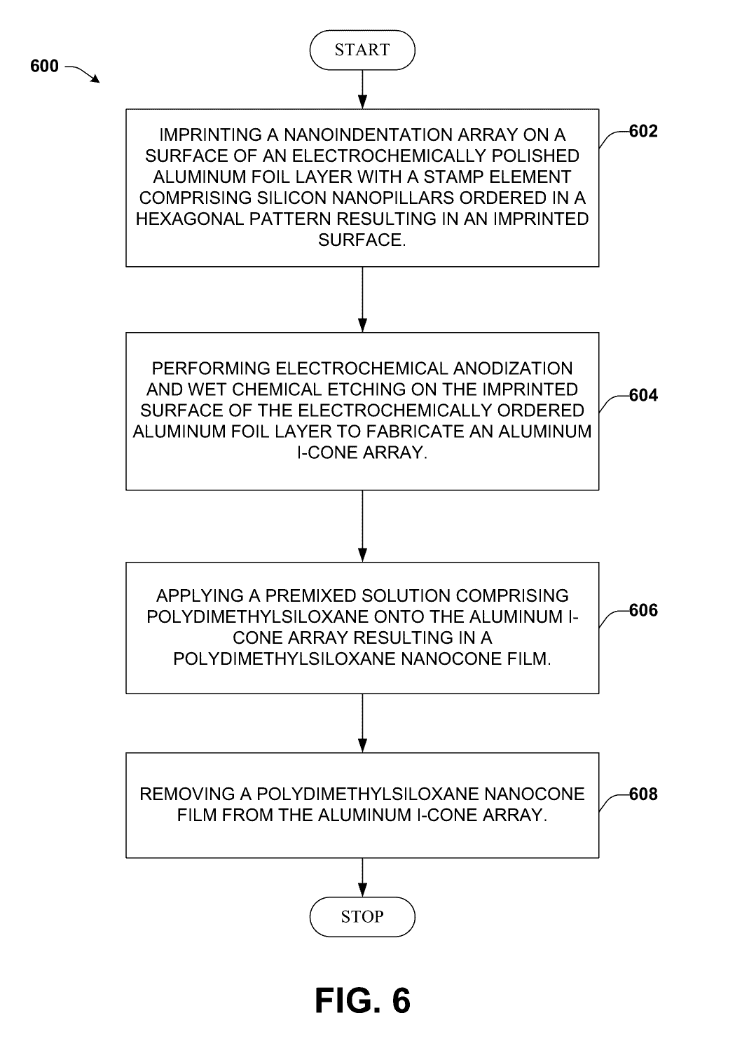

Turning now to FIGS. 6-8, illustrated are methodologies or flow diagrams in accordance with certain aspects of this disclosure. While, for purposes of simplicity of explanation, the disclosed methods are shown and described as a series of acts, the disclosed subject matter is not limited by the order of acts, as some acts may occur in different orders and/or concurrently with other acts from that shown and described herein. For example, those skilled in the art will understand and appreciate that a methodology can alternatively be represented as a series of interrelated states or events, such as in a state diagram. Moreover, not all illustrated acts may be required to implement a method in accordance with the disclosed subject matter.

Referring now to FIG. 6, presented is a flow diagram of a non-limiting example of a method 600 of fabricating a three-dimensional flexible nanocone film disclosed in this description in accordance with an embodiment. At 602, a nanoindentation array is imprinted on a surface of an electrochemically polished aluminum foil layer with a stamp element comprising silicon nanopillars ordered in a hexagonal pattern resulting in an imprinted surface. At 604, an electrochemical anodization and wet chemical etching process is performed on the imprinted surface of the electrochemically ordered aluminum foil layer to fabricate an aluminum i-cone array. At 606, a premixed solution comprising polydimethylsiloxane is applied onto the aluminum i-cone array resulting in a polydimethylsiloxane nanocone film. At 608, a polydimethylsiloxane nanocone film is removed from the aluminum i-cone array.

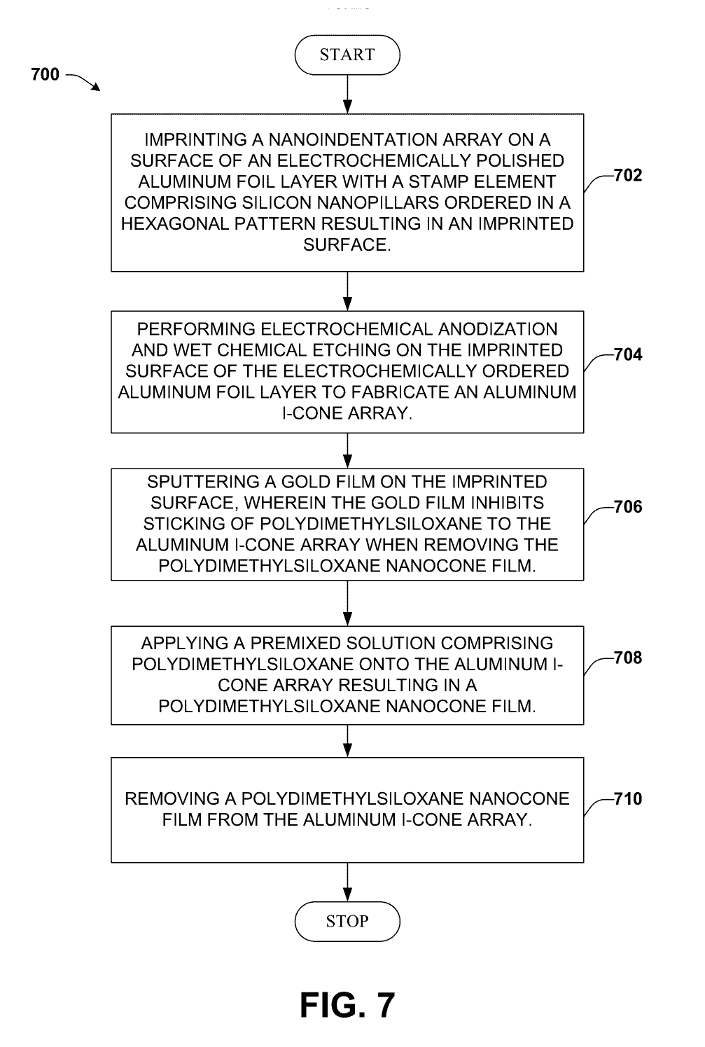

Referring now to FIG. 7, presented is a flow diagram of a non-limiting example of a method 700 of fabricating a three-dimensional flexible nanocone film disclosed in this description in accordance with an embodiment. At 702, a nanoindentation array is imprinted on a surface of an electrochemically polished aluminum foil layer with a stamp element comprising silicon nanopillars ordered in a hexagonal pattern resulting in an imprinted surface. At 704, an electrochemical anodization and wet chemical etching process is performed on the imprinted surface of the electrochemically ordered aluminum foil layer to fabricate an aluminum i-cone array. At 706, a gold film is sputtered on the imprinted surface, wherein the gold film inhibits sticking of polydimethylsiloxane to the aluminum i-cone array when removing the polydimethylsiloxane nanocone film. At 708, a premixed solution comprising polydimethylsiloxane is applied onto the aluminum i-cone array resulting in a polydimethylsiloxane nanocone film. At 710, a polydimethylsiloxane nanocone film is removed from the aluminum i-cone array.

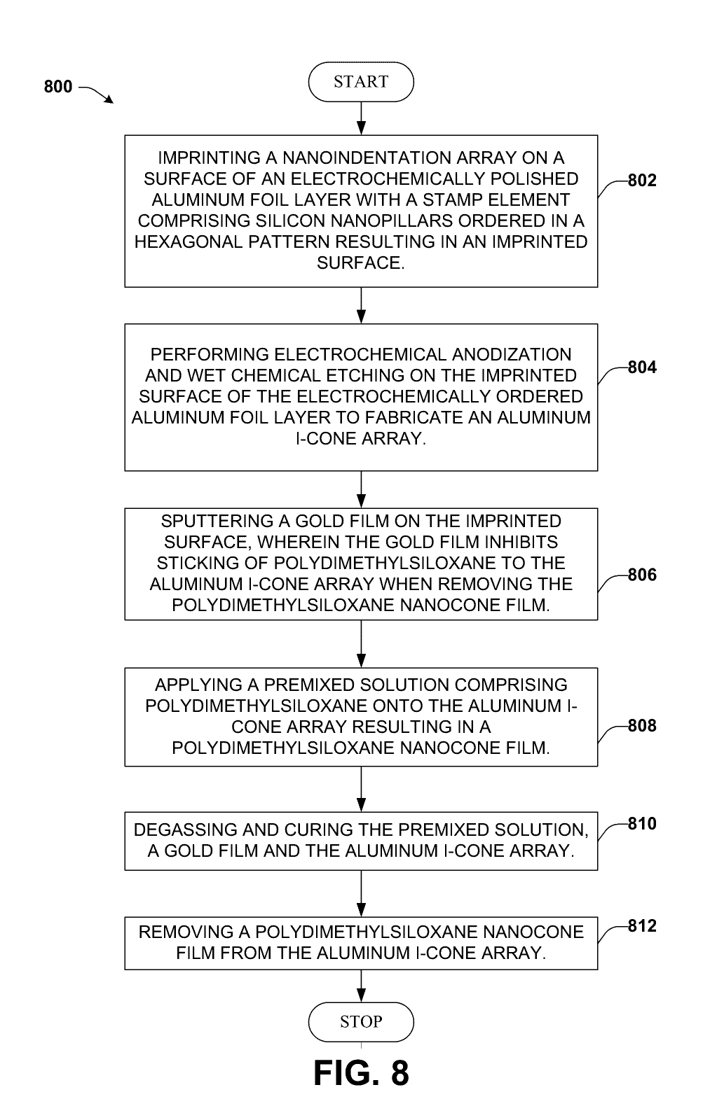

Referring now to FIG. 8, presented is a flow diagram of a non-limiting example of a method 800 of fabricating a three-dimensional flexible nanocone film disclosed in this description in accordance with an embodiment. At 802, a nanoindentation array is imprinted on a surface of an electrochemically polished aluminum foil layer with a stamp element comprising silicon nanopillars ordered in a hexagonal pattern resulting in an imprinted surface. At 804, an electrochemical anodization and wet chemical etching process is performed on the imprinted surface of the electrochemically ordered aluminum foil layer to fabricate an aluminum i-cone array. At 806, a gold film is sputtered on the imprinted surface, wherein the gold film inhibits sticking of polydimethylsiloxane to the aluminum i-cone array when removing the polydimethylsiloxane nanocone film. At 808, a premixed solution comprising polydimethylsiloxane is applied onto the aluminum i-cone array resulting in a polydimethylsiloxane nanocone film. At 810, the premixed solution, gold film, and the aluminum i-cone array is degassed and cured. At 810, a polydimethylsiloxane nanocone film is removed from the aluminum i-cone array.

In view of the exemplary devices described above, methodologies that may be implemented in accordance with the described subject matter will be better appreciated with reference to the flowcharts of the various figures. While for purposes of simplicity of explanation, the methodologies are shown and described as a series of blocks, it is to be understood and appreciated that the claimed subject matter is not limited by the order of the blocks, as some blocks may occur in different orders and/or concurrently with other blocks from what is depicted and described in this disclosure. Where non-sequential, or branched, flow is illustrated via flowchart, it can be appreciated that various other branches, flow paths, and orders of the blocks, may be implemented which achieve the same or a similar result. Moreover, not all illustrated blocks may be required to implement the methodologies described hereinafter.

In addition to the various embodiments described in this disclosure, it is to be understood that other similar embodiments can be used or modifications and additions can be made to the described embodiment(s) for performing the same or equivalent function of the corresponding embodiment(s) without deviating there from. Still further, nanocone film layers and nanocone film layer covered photovoltaic devices can share the performance of one or more functions described in this disclosure. Accordingly, the invention is not to be limited to any single embodiment, but rather can be construed in breadth, spirit and scope in accordance with the appended claims.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form.

What has been described above includes examples of devices and methods that provide advantages of the subject innovation. It is, of course, not possible to describe every conceivable combination of components or methodologies for purposes of describing the claimed subject matter, but one of ordinary skill in the art may recognize that many further combinations and permutations of the various embodiments described herein are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

What is claimed is:

1. A device, comprising:
a nanocone layer comprising a first material; and
a substrate layer comprising a second material, wherein the nanocone layer and the substrate layer form a flexible nanocone film that comprises an anti-reflective property, wherein the flexible nanocone film coats a photovoltaic device intended to absorb light and convert energy, and wherein the nanocone film facilitates increased light absorption by the photovoltaic device relative to the nanocone film coating being absent and increased energy conversion output of the photovoltaic device relative to the nanocone film coating being absent.

2. The device of claim 1, wherein the first material is at least one of a polydimethylsiloxane molded with an anodic alumina, polycarbonate, polyimide, or a plastic material.

3. The device of claim 1, wherein the first material is transparent.

4. The device of claim 1, wherein the second material is aluminum.

5. The device of claim 1, wherein the nanocone layer coats a top surface of the photovoltaic device, and wherein the top surface has the greatest exposure to sunlight.

6. The device of claim 1, wherein the flexible nanocone film is superhydrophobic, and wherein a water droplet located at a top surface of the flexible nanocone film contacts at an angle greater than or equal to 150 degrees relative to the top surface.

7. The device of claim 6, wherein the superhydrophobic flexible nanocone film facilitates water removal and dust removal from the photovoltaic device.

8. A method, comprising:
imprinting a nanoindentation array on a surface of an electrochemically polished aluminum foil layer with a stamp element comprising silicon nanopillars ordered in a hexagonal pattern resulting in an imprinted surface;
performing electrochemical anodization and wet chemical etching on the imprinted surface of the electrochemically ordered aluminum foil layer to fabricate an aluminum i-cone array;
applying a premixed solution comprising polydimethylsiloxane onto the aluminum i-cone array resulting in a polydimethylsiloxane nanocone film; and
removing a polydimethylsiloxane nanocone film from the aluminum i-cone array.

9. The method of claim 8, further comprising degassing and curing the premixed solution, a gold film and the aluminum i-cone array.

10. The method of claim 8, further comprising sputtering a gold film on the imprinted surface, wherein the gold film inhibits sticking of polydimethylsiloxane to the aluminum i-cone array when removing the polydimethylsiloxane nanocone film.

11. The method of claim 8, wherein the electrochemical anodization and the wet chemical etching are performed in an acidic solution.

12. The method of claim 11, wherein a direct-current voltage is applied to the aluminum i-cone array.

13. The method of claim 8, wherein the electrochemical anodization is performed using a mixture of citric acid, phosphoric acid, ethylene glycol and distilled water.

14. The method of claim 12, wherein anodic aluminum oxide is produced on the imprinted surface by applying a direct current voltage ranging between 200V-750V to the aluminum i-cone array.

15. The method of claim 11, wherein the wet chemical etching in the acidic solution produces a 3-D nanostructures on the imprinted surface.

16. The method of claim 8, wherein the nanoindentation array comprises a nanohole array pattern or an inversed nanocone array pattern.

17. The method of claim 8, wherein an ordering of the nanoindentation comprises a hexagonal shaped or a square shaped pattern.

18. A device, comprising:
a photovoltaic cell comprising a cadmium telluride material; and
a polydimethylsiloxane nanocone film covering a surface of the photovoltaic cell, wherein the polydimethylsiloxane nanocone film comprises a nanocone array pattern layer and a substrate layer, and wherein the photovoltaic cell has enhanced anti-reflective properties as compared to the photovoltaic cell absent the polydimethylsiloxane nanocone film covering, increased energy conversion capabilities as compared to the photovoltaic cell absent the polydimethylsiloxane nanocone film covering, and increased energy output as compared to the photovoltaic cell absent the polydimethylsiloxane nanocone film covering.

19. The device of claim 18, wherein the nanocone array pattern layer comprises at least two nanocones according to a pattern comprising a pitch of at least 1 μm and a height of at least 1 μm.

20. The device of claim 18, wherein an increase in anti reflective properties occurs in response to one or more light rays being incident to the device at an angle ranging from 0° to 60°.

21. The device of claim 18, wherein the device has an increased hydrophobic property as compared to the device absent the polydimethylsiloxane nanocone film covering, and wherein the increased hydrophobic property facilitates removal of debris from the device by promoting water to drip off the polydimethylsiloxane nanocone film covering while carrying away debris.

22. The device of claim 18, wherein the photovoltaic cell comprises a copper indium gallium selenide photovoltaic cell or a silicon photovoltaic cell.
